(19) United States
(12) Patent Application Publication
(10) Pub. No.: US 2026/0096148 A1
(43) Pub. Date: Apr. 2, 2026

(54) ULTRA-THIN TWO-DIMENSIONAL (2D) NANOSHEET FIELD EFFECT TRANSISTOR WITH MIDDLE-OF-LINE COPPER CONTACTS

(71) Applicant: International Business Machines Corporation, Armonk, NY (US)

(72) Inventors: Kevin Wayne Brew, Niskayuna, NY (US); Henry T. Crawford-Eng, Bedford, NH (US); Alexander Reznicek, Troy, NY (US); Jingyun Zhang, Albany, NY (US)

(21) Appl. No.: 18/903,060

(22) Filed: Oct. 1, 2024

(51) Int. Cl. H01L 29/423; H01L 21/8234; H01L 27/088; H01L 29/06; H01L 29/24; H01L 29/66; H01L 29/775; H01L 29/786

(52) U.S. Cl. CPC H10D 30/6735; H10D 30/014; H10D 30/43; H10D 30/6757; H10D 62/121; H10D 62/80; H10D 84/0128; H10D 84/0149; H10D 84/038; H10D 84/83

(57) ABSTRACT

A nanosheet field effect transistor (FET) structure is provided. The nanosheet FET structure includes a gate stack. The gate gate stack includes dielectric layers and ultrathin nanosheets including a first transition metal dichalcogenide (TMDC). The ultrathin nanosheets are interleaved with neighboring dielectric layer pairs to form combination layers. The gate stack further includes gate metal layers interleaved with the combination layers, first and second contacts and a conformal liner. The first and second contacts include copper disposed on opposite sides of the gate stack. The conformal liner includes a second TMDC. The conformal liner is interposed between the gate stack and the first and second contacts.

### BACKGROUND

The present disclosure generally relates to fabrication methods and resulting structures for semiconductor devices. More specifically, the present disclosure relates to a semiconductor device with an ultra-thin two-dimensional (2D) nanosheet field effect transistor (FET).

A transistor is a semiconductor device used to amplify or switch electrical signals and power and is one of the basic building blocks of modern electronics. An FET is a type of transistor that uses an electric field to control the flow of current in a semiconductor. An FET has three terminals: a source, a gate and a drain. FETs control the flow of current by the application of a voltage to the gate, which in turn alters the conductivity between the drain and the source.

### SUMMARY

According to an aspect of the disclosure, a nanosheet field effect transistor (FET) structure is provided. The nanosheet FET structure includes a gate stack. The gate stack includes dielectric layers and ultrathin nanosheets including a first transition metal dichalcogenide (TMDC). The ultrathin nanosheets are interleaved with neighboring dielectric layer pairs to form combination layers. The gate stack further includes gate metal layers interleaved with the combination layers, first and second contacts and a conformal liner. The first and second contacts include copper disposed on opposite sides of the gate stack. The conformal liner includes a second TMDC. The conformal liner is interposed between the gate stack and the first and second contacts. In accordance with one or more additional embodiments, by utilizing an out-of-plane 2D TMDC with copper barrier properties, it is possible to have direct ultrathin contact to a TMDC channel while enabling the use of a local copper contact.

According to an aspect of the disclosure, a nanosheet field effect transistor (FET) structure is provided and includes a gate stack. The gate stack includes interfacial adhesion layers (IALs), ultrathin nanosheets and gate metal layers. The ultrathin nanosheets include a non-silicate material. The ultrathin nanosheets are interleaved with neighboring IAL pairs to form combination layers. The gate metal layers are interleaved with the combination layers. The gate stack further includes first and second contacts and a conformal liner. The first and second contacts include metallic material disposed on opposite sides of the gate stack. The conformal liner is interposed between the gate stack and the first and second contacts. The non-silicate material has higher in-plane conductivity than material of the conformal liner. The material of the conformal liner has higher out-of-plane conductivity than the non-silicate material. The material of the conformal liner is capable of preventing diffusion of the metallic material into the non-silicate material. In accordance with one or more additional embodiments, by utilizing an out-of-plane 2D TMDC with copper barrier properties, it is possible to have direct ultrathin contact to a TMDC channel while enabling the use of a local copper contact.

According to an aspect of the disclosure, a method of assembling a nanosheet field effect transistor (FET) structure is provided. The method includes forming a gate stack on a substrate. The gate stack includes dielectric layers, ultrathin nanosheets and gate metal layers. The ultrathin nanosheets include a first transition metal dichalcogenide (TMDC). The ultrathin nanosheets are interleaved with neighboring dielectric layer pairs to form combination layers. The gate metal layers are interleaved with the combination layers. The method further includes modifying the gate stack by recessing the dielectric layers and the gate metal layers from opposite ends of the ultrathin nanosheets, forming a conformal liner including a second TMDC around the gate stack and forming copper contacts contacting the conformal liner at opposite sides of the gate stack. In accordance with one or more additional embodiments, by utilizing an out-of-plane 2D TMDC with copper barrier properties, the method makes it possible to have direct ultrathin contact to a TMDC channel while enabling the use of a local copper contact.

Additional technical features and benefits are realized through the techniques of the present disclosure. Embodiments and aspects of the disclosure are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the disclosure are apparent from the following detailed description taken in conjunction with the accompanying drawings in which:

FIG. 1 is a side view of a nanosheet FET structure in accordance with one or more embodiments;

FIG. 2 is an enlarged side view of a portion of a nanosheet FET structure with outer and inner liners in accordance with one or more embodiments;

FIG. 3 is a flow diagram illustrating a method of assembling a nanosheet FET structure in accordance with one or more embodiments;

FIG. 4 is a side view of an initial nanosheet FET structure in accordance with one or more embodiments;

FIG. 5 is a side view of a secondary nanosheet structure following selective recession of interfacial adhesion layers (IALs) and metal gate layers executed with respect to the initial nanosheet FET structure of FIG. 4 in accordance with one or more embodiments;

FIG. 6 is a side view of a third nanosheet structure following dummy layer formation, fill and planarization operations, lithographic definition of S/D regions and dummy liner pull and implantation with top dielectric masking or gas phase material tuning executed with respect to the secondary nanosheet FET structure of FIG. 5 in accordance with one or more embodiments; and

FIG. 7 is a side view of a fourth nanosheet structure following conformal metal deposition executed with respect to the third nanosheet FET structure FIG. 6 in accordance with one or more embodiments.

The diagrams depicted herein are illustrative. There can be many variations to the diagram or the operations described therein without departing from the spirit of the disclosure. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two or three digit reference numbers. With minor exceptions, the leftmost digit(s) of each reference number correspond to the figure in which its element is first illustrated.

### DETAILED DESCRIPTION

According to an aspect of the disclosure, a nanosheet field effect transistor (FET) structure is provided. The nanosheet FET structure includes a gate stack. The gate stack includes dielectric layers and ultrathin nanosheets including a first transition metal dichalcogenide (TMDC). The ultrathin nanosheets are interleaved with neighboring dielectric layer pairs to form combination layers. The gate stack further includes gate metal layers interleaved with the combination layers, first and second contacts and a conformal liner. The first and second contacts include copper disposed on opposite sides of the gate stack. The conformal liner includes a second TMDC. The conformal liner is interposed between the gate stack and the first and second contacts. In accordance with one or more additional embodiments, by utilizing an out-of-plane 2D TMDC with copper barrier properties, it is possible to have direct ultrathin contact to a TMDC channel while enabling the use of a local copper contact.

In accordance with one or more additional embodiments, the nanosheet FET structure further includes a semiconductor substrate on which the gate stack is disposed and the gate stack further includes a bottom dielectric layer and an upper dielectric layer for lithographic compatibility.

In accordance with one or more additional embodiments, the gate stack includes at least four of the ultrathin nanosheets which represents an increase in channel number over conventional semiconductor devices that only have three channels.

In accordance with one or more additional embodiments, the ultrathin nanosheets protrude in opposite side directions from the neighboring dielectric layer pairs so that low resistance contact interfaces are provided on both sides of the gate stack.

In accordance with one or more additional embodiments, the ultrathin nanosheets protrude in the opposite side directions from the neighboring dielectric layer pairs by about 5-7 nm which provides for significant surface area for contact interfaces.

In accordance with one or more additional embodiments, the ultrathin nanosheets have a thickness of <1 nm which is thinner than conventional channel thicknesses without sacrificing electron mobility.

In accordance with one or more additional embodiments, the conformal liner has a thickness of <about 1 nm while providing out-of-plane conductivity.

In accordance with one or more additional embodiments, the first TMDC has higher in-plane conductivity than the second TMDC, the second TMDC has higher out-of-plane conductivity than the first TMDC and the second TMDC is capable of preventing copper diffusion into the first TMDC. This allows for optimized conduction along the contacts and between the contacts while preventing copper diffusion from the contacts to the channels.

In accordance with one or more additional embodiments, the first TMDC includes at least one or more of molybdenum sulfide, tungsten selenium or tungsten sulfide to provide for high in-plane conductivity and the second TMDC includes at least tantalum sulfide to provide for high out-of-plane conductivity and to prevent copper diffusion.

In accordance with one or more additional embodiments, the dielectric layers comprise at least an interfacial adhesion layer (IAL) to maintain integrity of the gate stack.

In accordance with one or more additional embodiments, the conformal liner includes an outer liner including the second TMDC and an inner liner formed of isotropically conductive material and interposed between the outer liner and the gate stack for increased out-of-plane conductivity.

According to an aspect of the disclosure, a nanosheet field effect transistor (FET) structure is provided and includes a gate stack. The gate stack includes interfacial adhesion layers (IALs), ultrathin nanosheets and gate metal layers. The ultrathin nanosheets include a non-silicate material. The ultrathin nanosheets are interleaved with neighboring IAL pairs to form combination layers. The gate metal layers are interleaved with the combination layers. The gate stack further includes first and second contacts and a conformal liner. The first and second contacts include metallic material disposed on opposite sides of the gate stack. The conformal liner is interposed between the gate stack and the first and second contacts. The non-silicate material has higher in-plane conductivity than material of the conformal liner. The material of the conformal liner has higher out-of-plane conductivity than the non-silicate material. The material of the conformal liner is capable of preventing diffusion of the metallic material into the non-silicate material. In accordance with one or more additional embodiments, by utilizing an out-of-plane 2D TMDC with copper barrier properties, it is possible to have direct ultrathin contact to a TMDC channel while enabling the use of a local copper contact.

In accordance with one or more additional embodiments, the ultrathin nanosheets protrude in opposite side directions from the neighboring IAL pairs so that low resistance contact interfaces are provided on both sides of the gate stack.

In accordance with one or more additional embodiments, the non-silicate material includes a first transition metal dichalcogenide (TMDC) and the material of the conformal liner includes a second TMDC. This allows for optimized conduction along the contacts and between the contacts while preventing copper diffusion from the contacts to the channels.

In accordance with one or more additional embodiments, the first TMDC includes at least one or more of molybdenum sulfide, tungsten selenium or tungsten sulfide to provide for high in-plane conductivity and the second TMDC includes at least tantalum sulfide to provide for high out-of-plane conductivity and to prevent copper diffusion.

In accordance with one or more additional embodiments, the conformal liner includes an outer liner including the second TMDC and an inner liner interposed between the outer liner and the gate stack and formed of isotropically conductive material for increased out-of-plane conductivity.

According to an aspect of the disclosure, a method of assembling a nanosheet field effect transistor (FET) structure is provided. The method includes forming a gate stack on a substrate. The gate stack includes dielectric layers, ultrathin nanosheets and gate metal layers. The ultrathin nanosheets include a first transition metal dichalcogenide (TMDC). The ultrathin nanosheets are interleaved with neighboring dielectric layer pairs to form combination layers. The gate metal layers are interleaved with the combination layers. The method further includes modifying the gate stack by recessing the dielectric layers and the gate metal layers from opposite ends of the ultrathin nanosheets, forming a conformal liner including a second TMDC around the gate stack and forming copper contacts contacting the conformal liner at opposite sides of the gate stack. In accordance with one or more additional embodiments, by utilizing an out-of-plane 2D TMDC with copper barrier properties, the method makes it possible to have direct ultrathin contact to a TMDC channel while enabling the use of a local copper contact.

In accordance with one or more additional embodiments, the first TMDC has higher in-plane conductivity than the second TMDC, the second TMDC has higher out-of-plane conductivity than the first TMDC and the second TMDC is capable of preventing copper diffusion into the first TMDC. This allows for optimized conduction along the contacts and between the contacts while preventing copper diffusion from the contacts to the channels.

In accordance with one or more additional embodiments, the first TMDC includes at least one or more of molybdenum sulfide, tungsten selenium or tungsten sulfide to provide for high in-plane conductivity and the second TMDC includes at least tantalum sulfide to provide for high out-of-plane conductivity and to prevent copper diffusion.

In accordance with one or more additional embodiments, forming the conformal liner including the second TMDC around the gate stack includes forming an inner liner formed of isotropically conductive material around the gate stack and forming an outer liner comprising the second TMDC around the inner liner for increased out-of-plane conductivity.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the disclosure, nanosheet devices offer device performance improvements at lower power as compared to conventional finFET devices due to their gate-all-around (GAAFET) structure. In particular, nanosheet device structures can provide improved electrostatic control of the channel and high-current-drive capability. However, it has been found that the scaling of the gate length depends on thinning the channel body and, as the channel is thinned in silicon, carrier mobility is reduced due to surface roughness scattering of carriers.

Recently, 2D semiconductors such as transition metal dichalcogenides (TMDCs) have been scaled below 1 nm. It has been found that, when these materials are scaled down below 1 nm, they do not lose carrier density. TMDCs have therefore been investigated as replacements for silicon in the nanosheet FET device channel.

In addition to the above-noted concerns, contacts to source/drain (S/D) elements for silicon nanosheets have generally been heavily doped SiGe:B/Si:P and grown at channel edges with MOL contacts made of tungsten or cobalt with a dielectric liner forming a silicide used to make contact. Copper has often been avoided in the MOL due to its tendency to diffuse into and contaminate silicon channels. Such diffusion and contamination leads to deadened devices due to mid-level traps of copper in silicon.

Turning now to an overview of the aspects of the disclosure, one or more embodiments of the disclosure address the above-described shortcomings of the prior art by providing nanosheet FET structure including a gate stack, first and second contacts and a conformal liner. The gate stack includes dielectric layers, ultrathin nanosheets including a first TMDC and gate metal layers. The ultrathin nanosheets are interleaved with neighboring dielectric layer pairs to form combination layers. The gate metal layers are interleaved with neighboring combination layer pairs. The first and second contacts include copper and are disposed on opposite sides of the gate stack. The conformal liner includes a second TMDC and is interposed between the gate stack and the first and second contacts.

The above-described aspects of the disclosure address the shortcomings of the prior art by providing a nanosheet FET structure with a GAAFET configuration in which an out-of-plane conductive ultrathin (i.e., <3 nm) TMDC liner layer such as tantalum sulfide or molybdenum sulfide with copper barrier properties contacts a 2D nanosheet TMDC. An inner liner can be used for making a low resistivity contact between the 2D nanosheet TMDC and the TMDC liner layer. In some cases, optional implantation operations can be executed using recession of hexagonal boron nitride (h-BN)/gate dielectric stack to increase conductivity of certain TMDCs at channel edges to create S/D regions, which can prevent amorphization of the certain TMDCs. Contacts can be made of copper instead of bismuth, which is advantageous since bismuth has a melting point of <300° C. which will have implications on MOL/back-end-of-line (BEOL) processes.

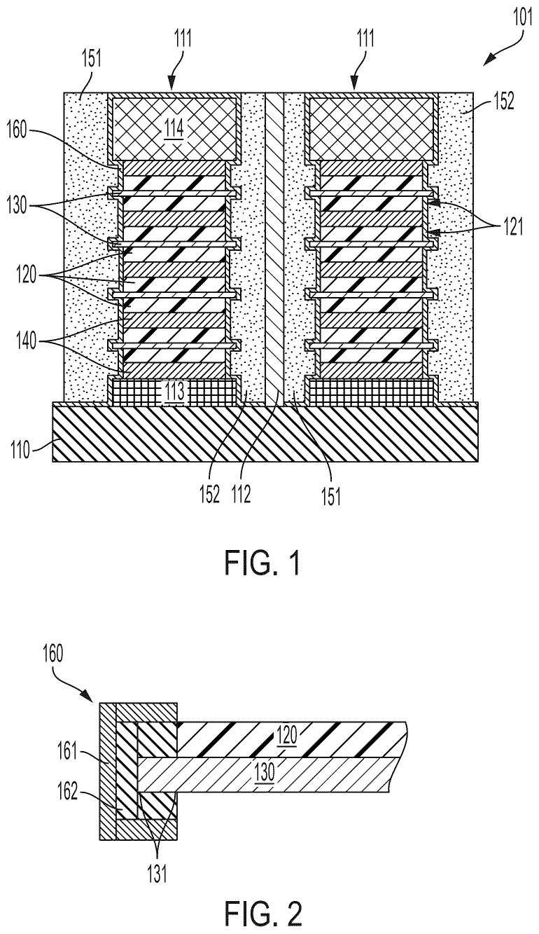

With reference to FIG. 1, a nanosheet FET structure 101 is provided and includes a semiconductor substrate 110 and one or more gate or GAAFET stacks 111 disposed on an upper surface of the semiconductor substrate 110. The following description will relate to the case in which two gate or GAAFET stacks 111 are disposed on the semiconductor substrate 110 but it is to be understood that this is done only for clarity and brevity and that fewer or greater numbers of gate or GAAFET stacks 111 can be disposed on the semiconductor substrate 110. Interlayer dielectric (ILD) 112 can be disposed between the gate or GAAFET stacks 111.

Each of the gate or GAAFET stacks 111 includes a bottom dielectric layer 113 and an upper dielectric layer 114. Between the bottom dielectric layer 113 and the upper dielectric layer 114, each of the gate or GAAFET stacks 111 further include dielectric layers 120, ultrathin nanosheets 130 and gate metal layers 140. The dielectric layers 120 can include or be provided as at least an interfacial adhesion layer (IAL) such as hexagonal boron nitride, other similar materials and/or combinations thereof. The ultrathin nanosheets 130 include a first TMDC and are respectively interleaved with (neighboring) dielectric layer 120 pairs to form combination layers 121. The gate metal layers 140 are interleaved with the combination layers 121.

For each of the gate or GAAFET stacks 111, the nanosheet FET structure 101 further includes first contact 151 and second contact 152, where the first and second contacts 151 and 152 each include metallic material, such as copper, other similar metals and/or combinations thereof and where the first and second contacts 151 and 152 are respectively disposed on opposite sides of each of the gate or GAAFET stacks 111. In addition, for each of the gate or GAAFET stacks 111, the nanosheet FET structure 101 further includes a conformal liner 160. The conformal liner 160 includes a second TMDC and is interposed between each of the gate or GAAFET stacks 111 and each of the corresponding first and second contacts 151 and 152. In accordance with one or more embodiments, the conformal liner 160 can have a thickness of about 1 nm or less or, in some cases, about 0.75 nm or less (but not 0 nm).

Although not required, the ultrathin nanosheets 130 can protrude in opposite side directions from the (neighboring) dielectric layer 120 pairs. In accordance with one or more embodiments, the ultrathin nanosheets 130 can protrude in the opposite side directions from the (neighboring) dielectric layer 120 pairs by about 5-7 nm. The following description will generally refer to the case in which the ultrathin nanosheets 130 protrude in the opposite side directions from the (neighboring) dielectric layer 120 pairs but it is to be understood that this is done only for clarity and brevity.

As used herein, the term “ultrathin” with respect to the ultrathin nanosheets 130 refers to the thickness of the ultrathin nanosheets 130, which can be about 1 nm or less. At this thickness, the gate or GAAFET stacks 111 can include at least four ultrathin nanosheets 130 without generating undesirable capacitances between the ultrathin nanosheets 130 and without forming the gate or GAAFET stacks 111 with an excessive height-to-width aspect ratio.

The first TMDC of the ultrathin nanosheets 130 can be characterized as having an high in-plane mobility of 50 to 100 cm²/V·s and the second TMDC of the conformal liner 160 can be characterized as having an out-of-plane conductivity of 0.1 to 0.5 μS/m. In any case, the first TMDC of the ultrathin nanosheets 130 can be characterized as having a higher in-plane conductivity than the second TMDC of the conformal liner 160, and the second TMDC of the conformal liner 160 can be characterized as having a higher out-of-plane conductivity than the first TMDC of the ultrathin nanosheets 130. In addition, the second TMDC of the conformal liner 160 can be characterized as being capable of preventing copper diffusion, with barrier energy defining diffusion behavior. In any case, the second TMDC of the conformal liner 160 can be characterized as being capable of preventing metallic, metal or copper diffusion from the first and second contacts 151 and 152 into the first TMDC of the ultrathin nanosheets 130.

The first TMDC of the ultrathin nanosheets 130 can include or be provided as a non-silicate material, such as at least one or more of molybdenum sulfide, tungsten selenium, tungsten sulfide, other similar materials and/or combinations thereof. The second TMDC of the conformal liner 160 can include or be provided as a non-silicate material such as at least tantalum sulfide, other similar materials and/or combinations thereof.

With the configuration and construction described above, utilizing the out-of-plane 2D TMDC of the conformal liner 160 with the copper barrier properties, it is possible to provide for direct ultrathin contact to the ultrathin nanosheets 130 and to enable local use of metallic materials, such as copper, for the first and second contacts 151 and 152. In turn, the use of metallic materials, such as copper, for the first and second contacts 151 and 152 avoids a need for use of bismuth for example, which has a relatively low melting point and interferes with MOL/BEOL processing. Also, the ultrathin nanosheets 130 form two-dimensional (2D) channels that offer improved gate control as compared to thicker or non-2D channels. This improved gate control leads to creation of significant accumulation of carriers and increased carrier density thus replacing a need for doping in the channels. Further, with the dielectric layers 120 including or being provided as at least the IAL, the dielectric layers 120 can effectively provide a protective layer to allow for gate material to be deposited around the channels formed by the ultrathin nanosheets 130 and to prevent mobility degradation from scattering against gate materials.

With continued reference to FIG. 1 and with additional reference to FIG. 2, the conformal liner 160 can include an outer liner 161, which includes the second TMDC, and an inner liner 162. The inner liner 162 can be formed of isotropically conductive material (i.e., material which is conductive in multiple directions) and is interposed between the outer liner 161 and the gate or GAAFET stacks 111 (i.e., between the outer liner 161 and exposed portions 131 of the ultrathin nanosheets 130, which are exposed by recession of the (neighboring) dielectric layer 120 pairs and recession of the gate metal layers 140). In accordance with one or more embodiments, the inner liner 162 can include or be provided as one or more semimetals, such as bismuth, indium-gallium arsenic, gallium nitride, other similar materials and combinations thereof, to form low contact resistance to the first TMDC of the ultrathin nanosheets 130 and the second TMDC of the conformal liner 160.

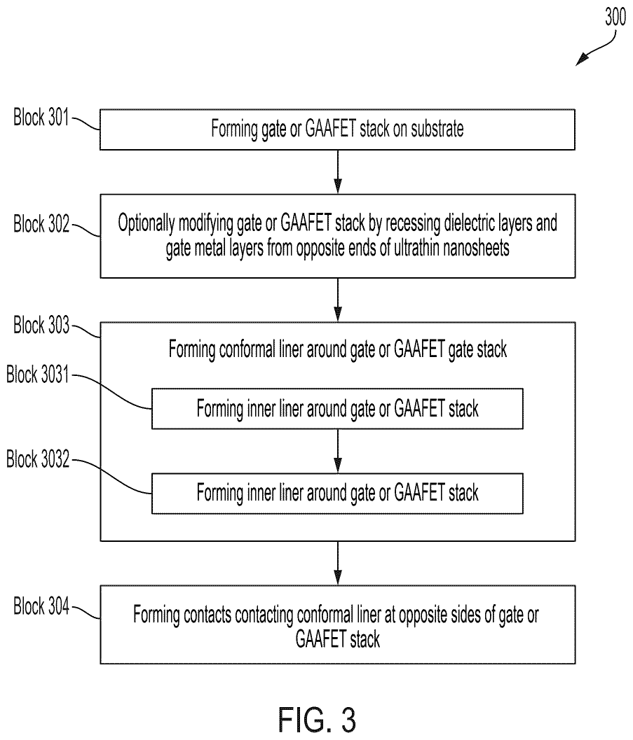

With continued reference to FIGS. 1 and 2 and with additional reference to FIG. 3, a method 300 of assembling a nanosheet FET structure, such as the nanosheet FET structure 101 of FIGS. 1 and 2, is provided. As shown in FIG. 3, the method 300 includes forming a gate or GAAFET stack on a substrate (block 301) where the gate or GAAFET stack is provided generally as described above with respect to the gate or GAAFET stacks 111 of FIG. 1. The method 300 further includes optionally modifying the gate or GAAFET stack by recessing the dielectric layers and the gate metal layers from opposite ends of the ultrathin nanosheets (block 302), forming a conformal liner including a second TMDC around the gate or GAAFET stack (block 303) and forming copper contacts contacting the conformal liner at opposite sides of the gate or GAAFET stack (block 304). As above, the first TMDC can be characterized as having higher in-plane conductivity than the second TMDC, the second TMDC can be characterized as having higher out-of-plane conductivity than the first TMDC and the second TMDC can be characterized as being capable of preventing copper diffusion into the first TMDC. Also as described above, the first TMDC can include or be provided as a non-silicate material, such as at least one or more of molybdenum sulfide, tungsten selenium, tungsten sulfide, other similar materials and/or combinations thereof, and the second TMDC can include or be provided as a non-silicate material, such as at least tantalum sulfide, other similar materials and/or combinations thereof. In addition, in accordance with one or more embodiments, the forming of the conformal liner of block 303 can include forming an inner liner formed of isotropically conductive material around the gate or GAAFET stack (block 3031) and forming an outer liner including the second TMDC around the inner liner (block 3032).

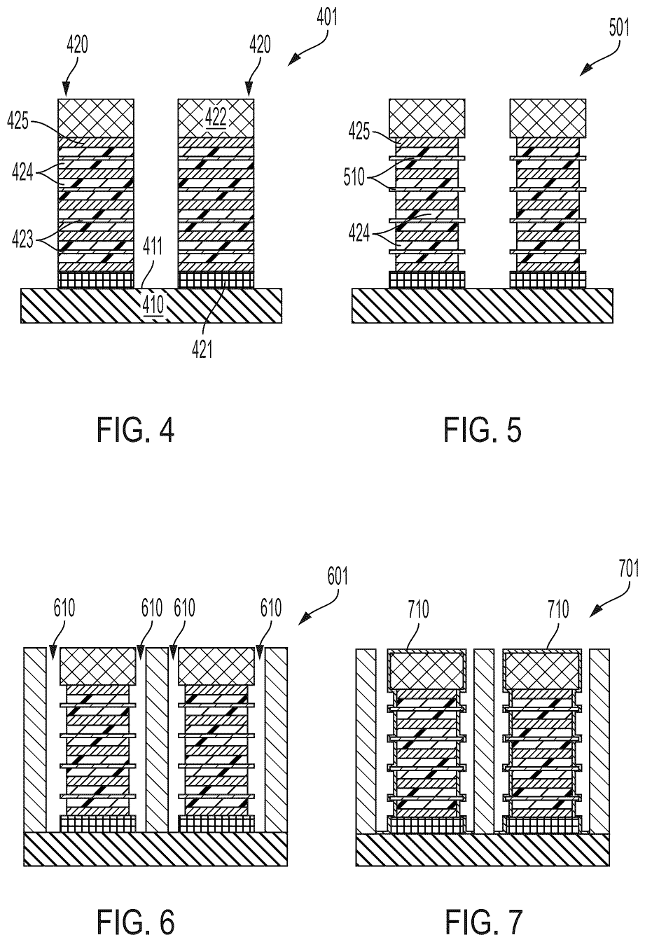

With continued reference to FIGS. 1 and 3 and with additional reference to FIGS. 4-7, the method 300 of FIG. 3 can be employed to arrive at the nanosheet FET structure 101 of FIG. 1.

As shown in FIG. 4, at an initial processing stage, an initial nanosheet FET structure 401 is provided and includes a semiconductor substrate 410 and block FET structures 420 disposed on an uppermost surface 411 of the semiconductor substrate 410. Each block FET structure 420 includes a bottom dielectric layer 421, an upper dielectric layer 422, ultrathin nanosheets formed of a first TMDC as described above forming 2D channels 423, IALs 424 above and below each 2D channel 423 to form combination layers, and metal gate layers 425 interleaved with the combination layers.

As shown in FIG. 5, at a secondary processing stage, a secondary nanosheet FET structure 501 is provided following selective recession of the IALs 424 and the metal gate layers 425 executed with respect to the initial nanosheet FET structure 401 of FIG. 4. This allows for hot implantation and/or gaseous doping at channel edges and formation of c-shaped contacts 510.

As shown in FIG. 6, at a third processing stage, a third nanosheet FET structure 601 is provided following dummy layer formation, fill and planarization operations, lithographic definition of S/D regions 610 and dummy liner pull and implantation with top dielectric masking or gas phase material tuning executed with respect to the secondary nanosheet FET structure 501 of FIG. 5.

As shown in FIG. 7, at a fourth processing stage, a fourth nanosheet FET structure 701 is provided following conformal metal deposition executed with respect to the third nanosheet FET structure 601 of FIG. 6 to form a conformal liner 710 of a second TMDC as described above. The conformal metal deposition to form the conformal liner 710 can be executed with sulfurization and/or selenization. Additionally or alternatively, the conformal metal deposition to form the conformal liner 710 can be executed so as to form outer and inner liners as described above.

Metal fill and chemical mechanical polishing (CMP) operations can be subsequently executed with respect to the fourth nanosheet structure 701 to arrive at the nanosheet FET structure 101 of FIG. 1.

Various embodiments of the present disclosure are described herein with reference to the related drawings. Alternative embodiments can be devised without departing from the scope of this disclosure. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments of the disclosure, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present disclosure will now be provided. Although specific fabrication operations used in implementing one or more embodiments of the present disclosure can be individually known, the described combination of operations and/or resulting structures of the present disclosure are unique. Thus, the unique combination of the operations described in connection with the fabrication of a semiconductor device according to the present disclosure utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present disclosure. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present disclosure have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A nanosheet field effect transistor (FET) structure, comprising:
a gate stack comprising:
dielectric layers;
ultrathin nanosheets comprising a first transition metal dichalcogenide (TMDC), the ultrathin nanosheets being interleaved with neighboring dielectric layer pairs to form combination layers; and
gate metal layers interleaved with the combination layers;
first and second contacts comprising copper disposed on opposite sides of the gate stack; and
a conformal liner comprising a second TMDC, the conformal liner being interposed between the gate stack and the first and second contacts.

2. The nanosheet FET structure according to claim 1, wherein:
the nanosheet FET structure further comprises a semiconductor substrate on which the gate stack is disposed, and
the gate stack further comprises a bottom dielectric layer and an upper dielectric layer.

3. The nanosheet FET structure according to claim 1, wherein the gate stack comprises at least four of the ultrathin nanosheets.

4. The nanosheet FET structure according to claim 1, wherein the ultrathin nanosheets protrude in opposite side directions from the neighboring dielectric layer pairs.

5. The nanosheet FET structure according to claim 4, wherein the ultrathin nanosheets protrude in opposite side directions from the neighboring dielectric layer pairs by about 5-7 nm.

6. The nanosheet FET structure according to claim 1, wherein the ultrathin nanosheets have a thickness of <1 nm.

7. The nanosheet FET structure according to claim 1, wherein the conformal liner has a thickness of <about 1 nm.

8. The nanosheet FET structure according to claim 1, wherein the first TMDC has higher in-plane conductivity than the second TMDC, the second TMDC has higher out-of-plane conductivity than the first TMDC and the second TMDC is capable of preventing copper diffusion into the first TMDC.

9. The nanosheet FET structure according to claim 1, wherein the first TMDC comprises at least one or more of molybdenum sulfide, tungsten selenium or tungsten sulfide and the second TMDC comprises at least tantalum sulfide.

10. The nanosheet FET structure according to claim 1, wherein the dielectric layers comprise at least an interfacial adhesion layer (IAL).

11. The nanosheet FET structure according to claim 1, wherein the conformal liner comprises:
an outer liner comprising the second TMDC; and
an inner liner formed of isotropically conductive material and interposed between the outer liner and the gate stack.

12. A nanosheet field effect transistor (FET) structure, comprising:
a gate stack comprising:
interfacial adhesion layers (IALs);
ultrathin nanosheets comprising a non-silicate material, the ultrathin nanosheets being interleaved with neighboring IAL pairs to form combination layers; and
gate metal layers interleaved with the combination layers;
first and second contacts comprising metallic material disposed on opposite sides of the gate stack; and
a conformal liner interposed between the gate stack and the first and second contacts,
the non-silicate material having higher in-plane conductivity than material of the conformal liner, the material of the conformal liner having higher out-of-plane conductivity than the non-silicate material and the material of the conformal liner being capable of preventing diffusion of the metallic material into the non-silicate material.

13. The nanosheet FET structure according to claim 12, wherein the ultrathin nanosheets protrude in opposite side directions from the neighboring IAL pairs.

14. The nanosheet FET structure according to claim 12, wherein the non-silicate material comprises a first transition metal dichalcogenide (TMDC) and the material of the conformal liner comprises a second TMDC.

15. The nanosheet FET structure according to claim 14, wherein the first TMDC comprises at least one or more of molybdenum sulfide, tungsten selenium or tungsten sulfide and the second TMDC comprises at least tantalum sulfide.

16. The nanosheet FET structure according to claim 14, wherein the conformal liner comprises:
an outer liner comprising the second TMDC; and
an inner liner interposed between the outer liner and the gate stack and formed of isotropically conductive material.

17. A method of assembling a nanosheet field effect transistor (FET) structure, the method comprising:
forming a gate stack on a substrate, the gate stack comprising:
dielectric layers;
ultrathin nanosheets comprising a first transition metal dichalcogenide (TMDC), the ultrathin nanosheets being interleaved with neighboring dielectric layer pairs to form combination layers; and
gate metal layers interleaved with the combination layers;
modifying the gate stack by recessing the dielectric layers and the gate metal layers from opposite ends of the ultrathin nanosheets;
forming a conformal liner comprising a second TMDC around the gate stack; and
forming copper contacts contacting the conformal liner at opposite sides of the gate stack.

18. The method according to claim 17, wherein the first TMDC has higher in-plane conductivity than the second TMDC, the second TMDC has higher out-of-plane conductivity than the first TMDC and the second TMDC is capable of preventing copper diffusion into the first TMDC.

19. The method according to claim 17, wherein the first TMDC comprises at least one or more of molybdenum sulfide, tungsten selenium or tungsten sulfide and the second TMDC comprises at least tantalum sulfide.

20. The method according to claim 17, wherein forming the conformal liner comprising the second TMDC around the gate stack comprises:
forming an inner liner formed of isotropically conductive material around the gate stack; and
forming an outer liner comprising the second TMDC around the inner liner.
